(19) United States
(12) Patent Application Publication
(10) Pub. No.: US 2011/0102978 A1
(43) Pub. Date: May 5, 2011

(54) INJECTION MOLDING METHOD FOR MOLDING A MOLDING PART

(75) Inventor: Peter Estlander, Malmo (SE)

(73) Assignee: SONY ERICSSON MOBILE COMMUNICATIONS AB, Lund (SE)

(21) Appl. No.: 12/609,215

(22) Filed: Oct. 30, 2009

(51) Int. Cl. B29C 45/42; H05K 5/00

(52) U.S. Cl. 361/679.01; 264/334; 425/556

(57) ABSTRACT

A method for injection molding a molding part in a molding cavity and a mold for injection molding a molding part are described.

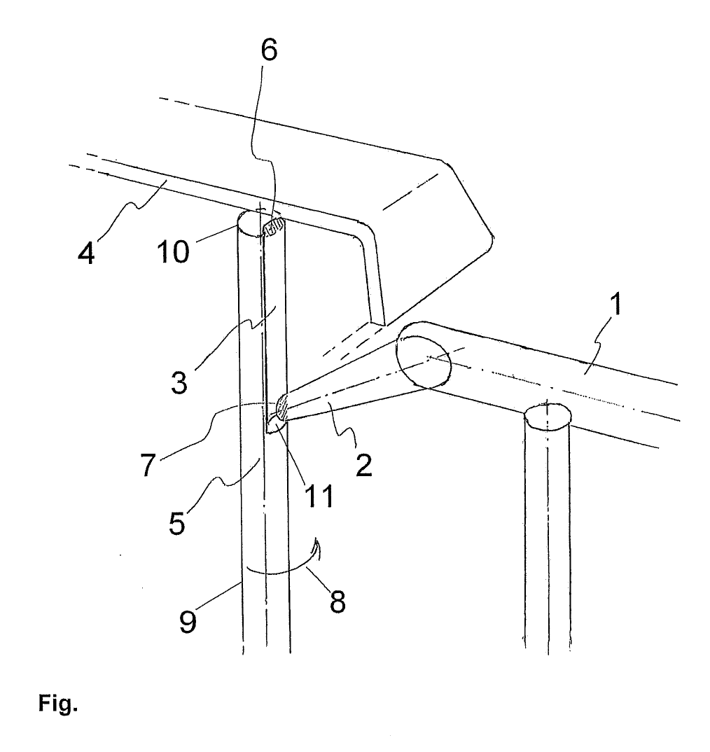

### BACKGROUND OF THE INVENTION

The present invention relates to a method for injection molding a molding part in a molding cavity, and a mold for injection molding a molding part.

### BRIEF SUMMARY OF THE INVENTION

According to an embodiment, a method for injection molding a molding part in a molding cavity is provided. According to the method, a cavity for establishing a fluid communication between a runner and the molding cavity is provided, wherein a gating end of the cavity is in contact with the molding cavity. Furthermore, an ejector pin is arranged inside the cavity. The ejector pin is configured such that in at least one position of the ejector pin inside the cavity, the fluid communication between the runner and the molding cavity is established. Furthermore, the ejector pin is rotatable inside the cavity around a longitudinal axis of the ejector pin, and an end of the ejector pin at the gating end of the cavity provides a shearing edge for shearing a gate from the molding part when the ejector pin is rotated around its longitudinal axis. According to the method, the molding material is injected into the molding cavity through the runner and the cavity. Then the ejector pin is rotated in the cavity around its longitudinal axis to shear the gate at the gating end.

The longitudinal axis of the ejector pin may be in parallel to the longitudinal axis of the cavity. The cavity may be a jump runner and the ejector pin may be arranged in the jump runner.

According to an embodiment, the method comprises arranging of a tunnel gate between the runner and a circumferential section of the cavity. The tunnel gate may have a conical shape and may provide a fluid communication between the runner and the cavity.

Furthermore, according to an embodiment, the ejector pin may be moved in a longitudinal direction towards the molding cavity for ejecting the molding part out of the molding cavity after the molding part has been molded in the molding cavity.

The molding material may be a plastic material. The runner may comprise a cold runner.

According to an embodiment, the cavity for establishing the fluid communication between the runner and the molding cavity comprises a cylindrical shape with a circular cross-section. The ejector pin may comprise a cylindrical shape, and the cylindrical shape of the ejector pin may have a cross-section of a segment of a circle. Furthermore, a diameter of the circle of the cross-section of the cylindrical shape of the ejector pin may be approximately equal to a diameter of the cylindrical shape of the cavity.

When molding plastic cover parts, especially decorative or cosmetic plastic cover parts, it is preferred to have a gate point inside an outer edge of the cover part. To accomplish this gate point being on an inner side of the plastic cover part, a so-called banana gate or a jump gate may be used. The banana gate is degated when the molding tool opens, but the banana gate has a narrow inlet making the plastic freeze early which may inhibit to hold a molding pressure long enough, and furthermore, the banana gate reduces the ejection pressure and generates shear stress in the plastic material going through the banana gate. Furthermore, with the banana gate there is a risk for a gate blush at a surface opposite to the gate or a tear out in an area around the gate. Finally, when tearing off the gate, gate remains may be left at the plastic part. A jump gate, on the other hand, may have a wider inlet avoiding for example a shear stress in the plastic material going through. However, the jump gate is not degated in the tool, but has to be cut manually or by special equipment. Therefore, according to the present invention, an ejector pin is rotatably provided in the jump gate and after injecting molding material into the molding cavity, the ejector pin is rotated in the jump runner to cut off the gate with a shearing edge of the ejector pin.

According to another embodiment of the present invention, a mold for injection molding a molding part is provided. The mold comprises a molding cavity for forming the molding part therein, a runner for providing molding material from an injection molding machine, a cavity for establishing a fluid communication between the runner and the molding cavity, and an ejector pin arranged inside the cavity. A gating end of the cavity is in contact with the molding cavity. The ejector pin is configured such that in at least one position of the ejector pin inside the cavity, the fluid communication between the runner and the molding cavity is established. Furthermore, the ejector pin is configured such that it is rotatable inside the cavity around a longitudinal axis of the ejector pin and that an end of the ejector pin at the gating end of the cavity provides a shearing edge for shearing off a gate from the molding part when the ejector pin is rotated around its longitudinal axis.

The mold may furthermore comprise a control unit for automatically rotating the ejector pin around its longitudinal axis to shear off the gate from the molding part after the molding material has been injected into the molding cavity.

The cavity may a jump runner, wherein the ejector pin may be arranged inside the jump runner.

The mold may further comprise a tunnel gate with a conical shape arranged between the runner and a circumferential section of the cavity. The tunnel gate may provide a fluid communication between the runner and the cavity.

According to an embodiment, the cavity for establishing the fluid communication between the runner and the molding cavity comprises a cylindrical shape with a circular cross-section. The ejector pin may comprise a cylindrical shape with a cross-section of a segment of a circle. A diameter of the circle of the cross-section of the cylindrical shape of the ejector pin may be approximately equal to a diameter of the circular cylindrical cavity.

According to another embodiment, a mobile device comprises a plastic part, for example a plastic cover part, manufactured according to an embodiment of the above-defined method. The mobile device may comprise a mobile phone, a personal digital assistant, a mobile navigation system, a mobile music player or a mobile computer.

Although specific features described in the above summary and in the following detailed description are described in connection with specific embodiments, it is to be understood that the features of the embodiments described can be combined with each other unless it is noted otherwise.

### BRIEF DESCRIPTION OF THE DRAWING

Hereinafter, exemplary embodiments of the invention will be described with reference to the drawings.

The only FIGURE shows schematically a perspective view of cavities in a mold for injection molding a molding part according to an embodiment of the present invention.

### DETAILED DESCRIPTION OF THE INVENTION

In the following, exemplary embodiments of the present invention will be described in detail. It is to be understood that the following description is given only for the purpose of illustrating the principles of the invention and it not to be taken in a limiting sense. Rather, the scope of the invention is defined only by the appended claims and not intended to be limited by the exemplary embodiments hereinafter.

It is to be understood that the features of the various exemplary embodiments described herein may be combined with each other unless specifically noted otherwise.

The FIGURE shows schematically a mold tool according to an embodiment of the present invention. The mold tool comprises a runner 1, for example a cold runner, a tunnel gate 2, a cavity 9 and a molding cavity 4. The molding cavity 4 is formed such that a plastic part, for example a plastic cover for a mobile device, is formed in the molding cavity 4 when the molding cavity 4 is filled with plastic material. The cavity 9 has a cylindrical shape with an open end of the cavity 9 being in connection with the molding cavity 4. An ejector pin 5 is arranged inside the cavity 9. The ejector pin 5 has a cylindrical shape extending inside the cavity 9 from a first end 10 at an interface between the cavity 9 and the molding cavity 4 to a (not shown) second end which may be connected to a control unit for controlling a movement of the ejector pin 5.

The first end 10 will be called in the following “gating end” where the plastic part in the molding cavity 4 has to be separated from plastic material in the cavity 9 after the plastic part has been molded in the molding cavity 4. Furthermore, the cavity 9 will be called “jump gate cavity” in the following.

Along the longitudinal axis of the ejector pin 5, the ejector pin 5 provides two different cross-sections. Starting from the (not shown) second end of the ejector pin 5, the ejector pin 5 has a circular cross-section with an outer diameter of approximately the same as an inner diameter of the jump gate cavity 9. Starting from the first end or gating end 10, the ejector pin 5 has a cross-section of a segment of a circle, wherein an outer diameter of the circle is approximately equal to an inner diameter of the jump gate cavity 9. A cross-section area of the circle segment may for example be in a range of 50-80% of the cross-section area of the full circle. A junction 11 between the section with the circlular cross-section and the section with the circle segment cross-section is selected such that the section with the circle segment cross-section extends from the gating end 10 to a connection 7 where the tunnel gate 2 connects the jump gate cavity 9 at a circumferential area of the jump gate cavity 9. Thus, a cavity 3 is present in the jump gate cavity 9 even when the ejector pin 5 is arranged inside the jump gate cavity 9. When the ejector pin 5 is arranged inside the jump gate cavity 9 as shown in the figure, this cavity 3 provides a fluid communication between the tunnel gate 2 and the molding cavity 4. Therefore, the cavity 3 provides a runner for molding material and will be called in the following “jump runner”. The section of the ejector pin 5 having the circular cross-section provides in cooperation with the jump gate cavity 9 a fluid tight sealing avoiding molding material to flow through the jump gate cavity 9 in the direction of the second end of the ejector pin 5.

The tunnel gate 2 may have a conical shape with the wider cross-section connected to the cold runner 1 and the more narrow cross-section connected at the connection 7. Thus, a fluid communication from the cold runner 1 via the tunnel gate 2 and the jump runner 3 to the molding cavity 4 is established when the ejector pin 5 is arranged inside the jump gate cavity 9 as shown in the FIGURE.

In the following, a method for molding a molding part with the above-described molding tool will be described in more detail.

First, the ejector pin 5 is arranged inside the jump gate cavity 9 such that a fluid communication between the tunnel gate 2 and the molding cavity 4 is established. This arrangement is shown in the figure. Then, molding material, for example molten plastic material, is injected from a (not shown) injection molding machine through the cold runner 1, the tunnel gate 2, and the jump runner 3 into the molding cavity 4. After sufficient molding material is injected and the molding cavity 4 is sufficiently filled with molding material, injection is stopped. After a predefined time, the molding material in the molding cavity is solidified. Furthermore, also at least a part of the molding material in the jump runner 3 is solidified and connected to the molding part inside the molding cavity 4 at a gating point 6 interfacing the molding cavity 4 with the jump runner 3. For separating the solidified molding material in the jump runner 3 from the molding part in the molding cavity 4, the ejector pin 5 is rotated around its longitudinal axis inside the jump gate cavity 9 as indicated by arrow 8 in the figure. The ejector pin 5 may be rotated for example about an angle of 60°. By rotating the ejector pin 5 around its longitudinal axis, the gating end 10 of the ejector pin 5 around its longitudinal axis, the gating end 10 of the ejector pin 5 will shear off the molding material inside the jump runner 3 from the molding material in the molding cavity 4.

To support shearing off the molding material from the molding material in the molding cavity 4, the ejector pin 5 may provide a shearing edge at the gating end 10.

Furthermore, by rotating the ejector pin 5 the molding material inside the jump runner 3 will sheared off from molding material inside the tunnel gate 2 at the connection 7.

The ejector pin 5 may be rotated before or during opening the molding tool for extracting the molding part from the molding tool. Furthermore, the ejector pin 5 may be moved in its longitudinal direction towards the molding cavity 4 to utilize extracting the molding part from the molding cavity 4.

Alternatively, the ejector pin 5 may be rotated during a movement in the longitudinal direction for ejecting the molding part. In this case, the molding part has to be prevented from rotating the same way as the ejector pin 5 to achieve the shearing at the gating point 6.

By shearing the molding material at gating point 6, a smooth surface without remains can be achieved at the gating point 6 of the molding part molded in the molding cavity 4.

While exemplary embodiments have been described above, various modifications may be implemented in other embodiments. For example, the cross-section of the section of the ejector pin 5 with the circle segment cross-section may have any other suitable kind of cross-section adapted to shear the molding material at the gating point 6. For example, instead of a circle segment, the cross-section of the ejector pin 5 may have a circle sector. Furthermore, the cross-section of the ejector pin may have a non-circular cross-section and the cavity 3 may have any suitable cross-section, e.g. a square groove cross-section or a cord cross-section, or may have a varying cross-section between the junction 11 and the gating point 6. Moreover, the rotating angle for shearing the molding material at the gating point 6 may be selected appropriately depending on the cross-section of the ejector pin at the gating end 10. Furthermore, the longitudinal direction of the jump gate cavity 9 and the ejector pin 5 may have any suitable direction with respect to the molding cavity 4 or the molding tool itself. For example, the longitudinal direction of the jump gate cavity 9 and the ejector pin 5 may be tilted with respect to the molding tool such that the longitudinal direction is perpendicular to a surface of the molding part at the gating end 10.

Finally, it is to be understood that all the embodiments described above are considered to be comprised by the present invention as it is defined by the appended claims.

What is claimed is:

1. An injection molding method for molding a molding part in a molding cavity, comprising:
providing a cavity for establishing a fluid communication between a runner and the molding cavity, a gating end of the cavity being in contact with the molding cavity,
arranging an ejector pin inside the cavity, the ejector pin being configured such that
in at least one position of the ejector pin inside the cavity, the fluid communication between the runner and the molding cavity is established,
the ejector pin is rotatable inside the cavity around a longitudinal axis of the ejector pin, and
an end of the ejector pin at the gating end of the cavity provides a shearing edge for shearing a gate from the molding part when the ejector pin is rotated around its longitudinal axis,
injecting molding material into the molding cavity through the runner and the cavity, and
rotating the ejector pin in the cavity around its longitudinal axis to shear the gate at the gating end.

2. The method according to claim 1, wherein the longitudinal axis of the ejector pin is in parallel to a longitudinal axis of the cavity.

3. The method according to claim 1, wherein the cavity comprises a jump runner with the ejector pin being arranged in the jump runner.

4. The method according to claim 1, wherein a tunnel gate having a conical shape is arranged between the runner and a circumferential section of the cavity, the tunnel gate providing a fluid communication between the runner and the cavity.

5. The method according to claim 1, further comprising:
moving the ejector pin in a longitudinal direction towards the molding cavity for ejecting the molding part from the molding cavity.

6. The method according to claim 1, wherein the molding material comprises a plastic material.

7. The method according to claim 1, wherein the runner comprises a cold runner.

8. The method according to claim 1, wherein the cavity for establishing the fluid communication between the runner and the molding cavity comprises a cylindrical shape.

9. The method according to claim 8, wherein the ejector pin comprises a cylindrical shape having a cross-section of a segment of a circle.

10. The method according to claim 9, wherein a diameter of the circle of the cross-section of the cylindrical shape of the ejector pin is approximately equal to a diameter of the cylindrical cavity.

11. A mold for injection molding a molding part, the mold comprising:
a molding cavity for forming the molding part therein,
a runner for providing molding material from an injection molding machine,
a cavity for establishing a fluid communication between the runner and the molding cavity, a gating end of the cavity being in contact with the molding cavity, and
an ejector pin arranged inside the cavity, the ejector pin being configured such that
in at least one position of the ejector pin inside the cavity the fluid communication between the runner and the molding cavity is established,
the ejector pin is rotatable inside the cavity around a longitudinal axis of the ejector pin, and
an end of the ejector pin at the gating end of the cavity provides a shearing edge for shearing a gate from the molding part when the ejector pin is rotated around its longitudinal axis.

12. The mold according to claim 11, further comprising a control unit for automatically rotating the ejector pin around its longitudinal axis to shear the gate from the molding part after the molding material has been injected into the molding cavity.

13. The mold according to claim 11, wherein the cavity comprises a jump runner with the ejector pin being arranged in the jump runner.

14. The mold according to claim 11, further comprising a tunnel gate having a conical shape, the tunnel gate being arranged between the runner and a circumferential section of the cavity, and the tunnel gate providing a fluid communication between the runner and the cavity.

15. The mold according to claim 11, wherein the cavity for establishing the fluid communication between the runner and the molding cavity comprises a cylindrical shape.

16. The mold according to claim 15, wherein the ejector pin comprises a cylindrical shape having a cross-section of a segment of a circle.

17. The mold according to claim 16, wherein a diameter of the circle of the cross-section of the cylindrical shape of the ejector pin is approximately equal to a diameter of the cylindrical cavity.

18. A mobile device comprising a plastic part manufactured according to the method defined in claim 1.

19. The mobile device according to claim 18, wherein the mobile device comprises a device selected from the group comprising a mobile phone, a personal digital assistant, a mobile navigation system, a mobile music player and a mobile computer.
